(19) United States
(12) Patent Application Publication
(10) Pub. No.: US 2026/0066025 A1
(43) Pub. Date: Mar. 5, 2026

(54) STORAGE DEVICE AND OPERATING METHOD OF STORAGE DEVICE

(71) Applicant: SAMSUNG ELECTRONICS CO., LTD., Suwon-si (KR)

(72) Inventor: HYEONSEOK OH, Suwon-si (KR)

(73) Assignee: SAMSUNG ELECTRONICS CO., LTD., Suwon-si (KR)

(21) Appl. No.: 19/189,939

(22) Filed: Apr. 25, 2025

(30) Foreign Application Priority Data
Aug. 30, 2024 (KR) 10-2024-0118134
Apr. 9, 2025 (KR) 10-2025-0046226

(51) Int. Cl. G11C 29/36; G11C 29/12; G11C 29/38

(52) U.S. Cl. CPC G11C 29/36; G11C 29/1201; G11C 29/38; G11C 2029/3602

(57) ABSTRACT

Provided is a storage device which includes a receiver configured to receive a reception signal, filter the reception signal to generate an internal signal, and extract data from the internal signal; a tester circuit configured to, in a test operation, generate a pattern signal and a jitter signal, combine the pattern signal and the jitter signal to output the reception signal to the receiver, receive the internal signal from the receiver, compare the pattern signal and the internal signal, and output a comparison result of the pattern signal and the internal signal as a test result; and a controller configured to receive the reception signal and the comparison result.

### CROSS-REFERENCE TO RELATED APPLICATION(S)

This application is based on and claims priority under 35 U.S.C. § 119 to Korean Patent Application Nos. 10-2024-0118134 filed on Aug. 30, 2024, and 10-2025-0046226, filed on Apr. 9, 2025, in the Korean Intellectual Property Office, the disclosure of which is herein incorporated by reference in its entirety.

### BACKGROUND

One or more example embodiments of the disclosure described herein relate to an electronic device, and more particularly, relate to a storage device with improved reliability and an operating method of the storage device.

A storage device may include a nonvolatile memory device and a memory controller configured to control the nonvolatile memory device. The memory controller may perform a write operation, a read operation, or an erase operation on the nonvolatile memory device depending on a request of an external host device or an internal policy.

The memory controller may communicate with the external host device. A length of a first communication path through which the memory controller communicates with the external host device may be longer than a length of a second communication path through which the memory controller communicates with the nonvolatile memory device. In this case, a jitter may occur when the memory controller communicates with the external host device.

The jitter may belong to a noise. For example, the jitter may mean that a disturbance occurs at a first signal (or a preceding/leading signal) and a second signal (or a following/trailing signal) due to an interference between a timing of the first signal and a timing of the second signal. The jitter may reduce a quality of communication and may cause an error in a communication process.

### SUMMARY

One or more example embodiments of the disclosure provide a storage device and an operating method of the storage device capable of improving a yield by internally collecting information of a jitter to be provided to a user.

One or more example embodiments of the disclosure provide a storage device and an operating method of the storage device capable of improving jitter-tolerance (JTOL) by internally collecting information of a jitter and performing an optimization operation based thereon.

According to an aspect of an example embodiment, a storage device includes a receiver configured to receive a reception signal, filter the reception signal to generate an internal signal, and extract data from the internal signal; a tester circuit configured to, in a test operation, generate a pattern signal and a jitter signal, combine the pattern signal and the jitter signal to output the reception signal to the receiver, receive the internal signal from the receiver, compare the pattern signal and the internal signal, and output a comparison result of the pattern signal and the internal signal as a test result; and a controller configured to receive the reception signal and the comparison result.

According to an aspect of an example embodiment, a storage device includes a receiver configured to receive a reception signal, filter the reception signal to generate an internal signal, and extract data from the internal signal; a tester circuit configured to, in a test operation, generate a pattern signal and a jitter signal, combine the pattern signal and the jitter signal to output the reception signal to the receiver, receive the internal signal from the receiver, compare the pattern signal and the internal signal, and output a comparison result of the pattern signal and the internal signal as a test result; and a controller configured to receive the reception signal and the comparison result. The controller is further configured to, in response to the comparison result indicating a fail that the pattern signal and the internal signal do not coincide with each other, perform an optimization operation of adjusting at least one offset of the receiver. The controller is further configured to, in response to the comparison result indicating a pass that the pattern signal and the internal signal coincide with each other, skip the optimization operation.

According to an aspect of an example embodiment, an operating method of a storage device which includes a receiver and a tester circuit includes performing, at the tester circuit, a test operation on the receiver by using a pattern signal and a jitter signal, and setting, at the tester circuit, offsets of the receiver depending on a result of the test operation. The offsets include default offsets of filters of the receiver according to at least one of a temperature range of the storage device and a voltage range of the storage device. The performing of the test operation includes (i) combining the pattern signal and the jitter signal to be input to the receiver; (ii) comparing a signal filtered by the receiver with the pattern signal; (iii) repeating operations (i) and (ii) while adjusting the jitter signal, and (iv) iterating a test loop including operations (i)-(iii) while adjusting at least one offset of the receiver, until the pattern signal and the filtered signal coincide with each other.

### BRIEF DESCRIPTION OF DRAWINGS

The above and other objects and features of the disclosure will become apparent by describing in detail example embodiments thereof with reference to the accompanying drawings.

FIG. 1 illustrates a first electronic device and a second electronic device according to one or more example embodiments of the disclosure.

FIG. 2 illustrates a receiver according to one or more example embodiments of the disclosure.

FIG. 3 illustrates an example of an operating method of an electronic device according to one or more example embodiments of the disclosure.

FIG. 4 illustrates an example of test results of test operations, which a controller stores in a memory according to one or more example embodiments of the disclosure.

FIG. 5 illustrates an example of a test result and a comparison result associated with one test operation according to one or more example embodiments of the disclosure.

FIG. 6 illustrates a first example in which an electronic device performs a post operation according to one or more example embodiments of the disclosure.

FIG. 7 illustrates an electronic device according to one or more example embodiments of the disclosure.

FIG. 8 illustrates an operating method of an electronic device according to one or more example embodiments of the disclosure.

FIG. 9 illustrates an example in which an electronic device performs an optimization operation, according to one or more example embodiments of the disclosure.

FIG. 10 illustrates another example in which an electronic device performs an optimization operation, according to one or more example embodiments of the disclosure.

FIG. 11A illustrates an example of an initial state of a pass window according to one or more example embodiments of the disclosure.

FIG. 11B illustrates an example in which a pass window is reduced according to one or more example embodiments of the disclosure.

FIG. 11C illustrates an example in which a pass window is additionally reduced according to one or more example embodiments of the disclosure.

FIG. 12 illustrates another example of an operating method of an electronic device according to one or more example embodiments of the disclosure.

FIG. 13 illustrates a storage device according to one or more example embodiments of the disclosure.

FIG. 14 is a block diagram illustrating a nonvolatile memory device according to one or more example embodiments of the disclosure.

FIG. 15 is a diagram illustrating a system according to one or more example embodiments of the disclosure.

### DETAILED DESCRIPTION

Below, one or more example embodiments of the disclosure will be described in detail and clearly to such an extent that an ordinary one in the art easily carries out the disclosure.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

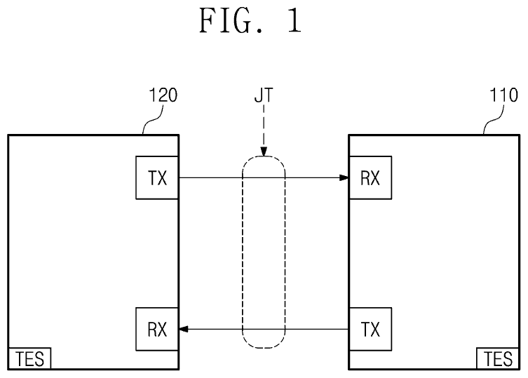

FIG. 1 illustrates a first electronic device 110 and a second electronic device 120 according to one or more example embodiments of the disclosure. Referring to FIG. 1, each of the first electronic device 110 and the second electronic device 120 may include a receiver RX, a transmitter TX, and a temperature sensor TES. The first electronic device 110 or the second electronic device 120 may receive a signal from the second electronic device 120 or the first electronic device 110 by using the receiver RX. The first electronic device 110 or the second electronic device 120 may transmit a signal to the second electronic device 120 or the first electronic device 110 by using the transmitter TX.

The first electronic device 110 or the second electronic device 120 may detect a temperature of the second electronic device 120 or the first electronic device 110 by using the temperature sensor TES. The first electronic device 110 or the second electronic device 120 may control operations of the first electronic device 110 or the second electronic device 120 by using information about the detected temperature.

A jitter JT may occur on a path through which the first electronic device 110 and the second electronic device 120 communicate with each other. The jitter JT may belong to a noise. For example, the jitter JT may mean that a disturbance occurs at a first signal (or a preceding/leading signal) and a second signal (or a following/trailing signal) due to an interference between the timing of the first signal and the timing of the second signal. The jitter JT may reduce a quality of communication and may cause an error in a communication process.

In a process of manufacturing the first electronic device 110 or the second electronic device 120, jitter-tolerance JTOL of the first electronic device 110 or the second electronic device 120 may be tested. The jitter-tolerance JTOL may indicate a capability of the first electronic device 110 or the second electronic device 120 capable of communicating a signal normally (or without an error) even if the jitter JT occurs.

In the process of manufacturing the first electronic device 110 or the second electronic device 120, an electronic device having the jitter-tolerance JTOL which is lower than a threshold level may be classified as a bad product. In the process of manufacturing the first electronic device 110 or the second electronic device 120, an electronic device having the jitter-tolerance JTOL which is equal to or higher than the threshold level may be classified as a good product. A ratio of good products to all the manufactured electronic devices may be a yield.

The jitter-tolerance JTOL of the first electronic device 110 or the second electronic device 120 may be measured by using an external device of the first electronic device 110 or the second electronic device 120. The external device may be connected to the first electronic device 110 or the second electronic device 120 and may measure the jitter-tolerance JTOL of the first electronic device 110 or the second electronic device 120.

In the process of manufacturing the first electronic device 110 or the second electronic device 120, a manner in which the first electronic device 110 or the second electronic device 120 is connected to the external device may change. For example, in a first manufacturing environment where the first electronic device 110 or the second electronic device 120 is manufactured on a wafer, the jitter-tolerance JTOL of the first electronic device 110 or the second electronic device 120 may be tested through a pad on the wafer. In a second manufacturing environment where the first electronic device 110 or the second electronic device 120 is packaged, the jitter-tolerance JTOL of the first electronic device 110 or the second electronic device 120 may be tested through a solder ball connected to the pad on the wafer.

In an embodiment, some electronic devices (e.g., first electronic devices) may have the jitter-tolerance JTOL equal to or higher than the threshold level in both the first manufacturing environment and the second manufacturing environment. In this case, the first electronic devices may be regarded as a good product.

Some electronic devices (e.g., second electronic devices) may be determined as having the jitter-tolerance JTOL lower than the threshold level in the first manufacturing environment and thus may be regarded as a bad product; however, the second electronic devices may be determined to be capable of having the jitter-tolerance JTOL equal to or higher than the threshold level in the second manufacturing environment. This may mean that an overkill that a good product is abnormally determined as a bad product occurs.

Some electronic devices (e.g., third electronic devices) may be determined as having the jitter-tolerance JTOL equal to or higher than the threshold level in the first manufacturing environment and thus may be regarded as a good product; however, the third electronic devices may be determined as having the jitter-tolerance JTOL lower than the threshold level in the second manufacturing environment. This may mean that an underkill that a bad product is temporarily determined as a good product occurs.

Also, in a third manufacturing environment where the connection with the external device is impossible, for example, when the first electronic device 110 or the second electronic device 120 is mounted in a system including the first electronic device 110 or the second electronic device 120, measurement of the jitter-tolerance JTOL of the first electronic device 110 or the second electronic device 120 is not possible.

The first electronic device 110 or the second electronic device 120 according to an embodiment of the disclosure may internally collect information of the jitter-tolerance JTOL without a support of the external device. The first electronic device 110 or the second electronic device 120 according to an embodiment of the disclosure may provide the collected information of the jitter-tolerance JTOL to the external device depending on a request of the external device. Accordingly, there may be measured the change in the jitter-tolerance JTOL according to the change in the manufacturing environment in the process of manufacturing the first electronic device 110 or the second electronic device 120.

Also, the first electronic device 110 or the second electronic device 120 according to an embodiment of the disclosure may perform an optimization operation of improving the jitter-tolerance JTOL of the receiver RX by adjusting offsets of the receiver RX based on the information of the measured jitter-tolerance JTOL or the collected information of the jitter-tolerance JTOL. The optimization operation may be performed based on the change in an ambient environment (e.g., a temperature and a voltage) of the first electronic device 110 or the second electronic device 120. Accordingly, even if the ambient environment changes, the first electronic device 110 or the second electronic device 120 may have the adaptively improved jitter-tolerance JTOL.

In an embodiment, one of the first electronic device 110 and the second electronic device 120 may be a storage device, and the other thereof may be a host device that may access the storage device. The first electronic device 110 and the second electronic device 120 may constitute a computing device such as a computer, a smartphone, or a smart pad.

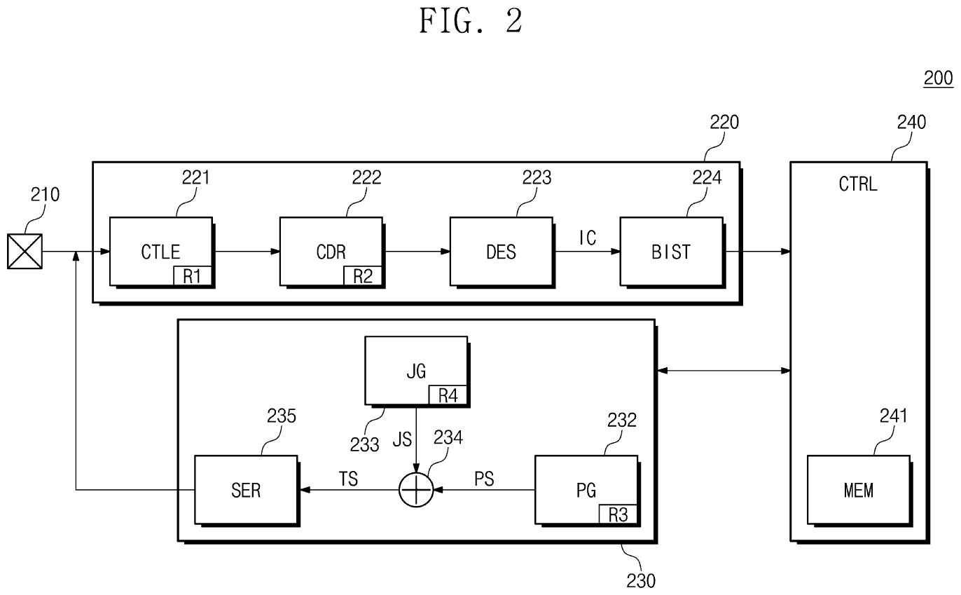

FIG. 2 illustrates an electronic device 200 according to one or more example embodiments of the disclosure. In an embodiment, the electronic device 200 may correspond to the first electronic device 110 or the second electronic device 120 of FIG. 1. Referring to FIGS. 1 and 2, the electronic device 200 may include a pad 210, a receiver 220, a tester circuit 230, and a controller (CTRL) 240. In an embodiment, the receiver 220 may correspond to the receiver RX described with reference to FIG. 1. The temperature sensor TES illustrated in FIG. 1 may be included in a component of the electronic device 200 although not separately illustrated in FIG. 2.

The pad 210 may be connected to an external device, for example, the first electronic device 110 or the second electronic device 120. The receiver 220 may receive a signal from the external device through the pad 210 or may receive a signal (may be referred to as reception signal) from the tester circuit 230. The receiver 220 may include a continuous time linear equalization (CTLE) circuit 221, a clock and data recovery (CDR) circuit 222, a deserialization (DES) circuit 223, and a Built-In Self-Test circuit (BIST) 224.

The CTLE circuit 221 may include a finite impulse response (FIR) filter that compensates for an inter-symbol interference (ISI). An order of the CTLE circuit 221 or a number of taps of the CTLE circuit 221 may be plural. The CTLE circuit 221 may include a first register R1. The first register R1 may store an offset associated with the CTLE circuit 221. The offset associated with the CTLE circuit 221 may affect a feature of a filtering operation performed by the CTLE circuit 221. For example, the offset of the CTLE circuit 221 may include coefficients respectively associated with orders of the CTLE circuit 221 and/or coefficients respectively associated with the taps of the CTLE circuit 221.

The CDR circuit 222 may extract a clock signal and a data signal from an output signal of the CTLE circuit 221. The CDR circuit 222 may include a second register R2. The second register R2 may store an offset associated with the CDR circuit 222. The offset associated with the CDR circuit 222 may affect a feature of an extraction operation performed by the CDR circuit 222. For example, the offset of the CDR circuit 222 may include an extraction timing and/or an extraction period of the CDR circuit 222 and/or a level of a comparison voltage to be compared with a level of the output signal of the CTLE circuit 221.

The DES circuit 223 may perform deserialization on the output signal of the CDR circuit 222. For example, the DES circuit 223 may convert signals continuously received from the CDR circuit 222 at two or more different timings into parallel signals and may output the parallel signals at the same time. An output of the DES circuit 223 may be an internal signal IC.

The BIST circuit 224 may receive the internal signal IC and may store the internal signal IC. The BIST circuit 224 may receive the internal signal IC from the DES circuit 223. The BIST circuit 224 may control a test operation in which the tester circuit 230 tests the jitter-tolerance JTOL of the receiver 220. The BIST circuit 224 may perform the test operation under control of the controller 240. For example, the BIST circuit 224 may bypass the internal signal IC to the controller 240 while the test operation is not performed.

The tester circuit 230 may test the jitter-tolerance JTOL of the receiver 220. The tester circuit 230 may include a pattern generator 232, a jitter generator 233, an adder 234, and a serialization (SER) circuit 235.

The pattern generator 232 may generate a pattern signal PS during the test operation. The pattern signal PS may be a signal having a waveform corresponding to bits which are specified by the user or are randomly generated. The pattern signal PS may have levels corresponding to levels of a signal which is provided from the external device through the pad 210 and is received by the receiver 220. For example, the levels of the pattern signal PS may be defined based on a communication standard which is used for the electronic device 200 to communicate with an external electronic device.

The pattern generator 232 may include a third register R3. The third register R3 may store information about a kind of the pattern signal PS (e.g., a kind of a pattern). For example, the third register R3 may store information about a number indicating the kind of the pattern signal PS and/or information about values of the bits of the pattern signal PS. The controller 240 may select the kind of the pattern signal PS to be generated by the pattern generator 232 from among a plurality of pattern signals capable of being generated by the pattern generator 232, by updating the information stored in the third register R3.

The jitter generator 233 may generate a jitter signal JS during the test operation. The jitter signal JS may be a sinusoidal signal. The jitter generator 233 may include a fourth register R4. The fourth register R4 may store information about a frequency and an amplitude of the jitter signal JS. The controller 240 may select a kind of the jitter signal JS to be generated by the jitter generator 233 from among a plurality of jitter signals capable of being generated by the jitter generator 233, by updating the information stored in the fourth register R4.

The adder 234 may generate a test signal TS by combining the pattern signal PS output from the pattern generator 232 and the jitter signal JS output from the jitter generator 233. For example, the adder 234 may sum up the pattern signal PS and the jitter signal JS on a time domain.

The SER circuit 235 may serialize the test signal TS. The SER circuit 235 may classify values of the test signal TS simultaneously received into two or more sets and may sequentially output the two or more sets.

When the communication with the external device is made, the tester circuit 230 may be deactivated. The receiver 220 may filter a signal received from the external device through the pad 210, to be transferred to the controller 240.

When the communication with the external device is not made, the tester circuit 230 may perform the test operation. The tester circuit 230 may transfer the test signal TS to the receiver 220. The receiver 220 may filter the test signal TS to generate the internal signal IC. The BIST circuit 224 may detect a number of error bits or a bit error rate in the internal signal IC. When the number of error bits or the bit error rate is less than a threshold value, the BIST circuit 224 may determine “PASS”. When the number of error bits or the bit error rate is equal to or greater than the threshold value, the BIST circuit 224 may determine “FAIL”. The BIST circuit 224 may transfer a pass or fail result to the controller 240. In other words, when the pattern signal PS and the internal signal IC coincide with each other, the BIST circuit 224 is configured to output pass information as a comparison result, and when the pattern signal PS and the internal signal IC do not coincide with each other, the BIST circuit 224 is configured to output fail information as the comparison result.

In an embodiment, the controller 240 may select a plurality of test loops in one test operation. In each test loop, the controller 240 may select a kind of the pattern signal PS, a frequency of the jitter signal JS, and an amplitude of the jitter signal JS. During one test operation, the BIST circuit 224 may provide the controller 240 with pieces of pass information or fail information about various test signals TS.

When the test operation is not performed, the controller 240 may receive a communication signal from the external device through the receiver 220. In the test operation, the controller 240 may receive comparison results (e.g., as test results), that is, pieces of pass or fail information from the receiver 220. The controller 240 may store the communication signal or the comparison results in a memory (MEM) 241. For example, the memory 241 may include a random access memory such as a static random access memory (SRAM), a dynamic RAM (DRAM), a magnetic RAM (MRAM), a phase-change RAM (PRAM), a ferroelectric RAM (FRAM), or a resistive RAM (RRAM).

The controller 240 may perform a post operation, based on a test result stored in the memory 241. In an embodiment, the electronic device 200 may be implemented with a storage device. The controller 240 may be configured to access an additionally provided nonvolatile memory device in addition to a reception operation through the receiver 220 and the test operation through the tester circuit 230.

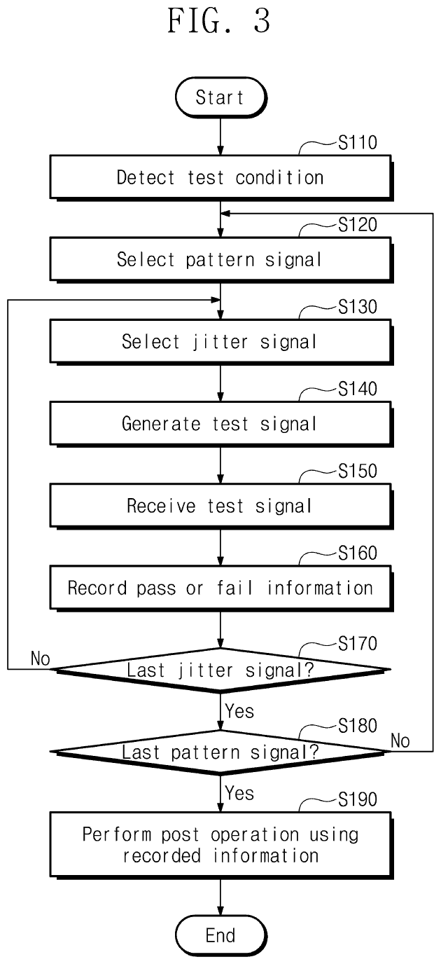

FIG. 3 illustrates an example of an operating method of the electronic device 200 according to one or more example embodiments of the disclosure. Referring to FIGS. 2 and 3, in operation S110, the electronic device 200 may detect a test condition. For example, the controller 240 of the electronic device 200 may detect whether the test condition is satisfied. For example, when a power starts to be supplied to the electronic device 200 (e.g., when the electronic device 200 is powered on), the controller 240 may detect that the test condition is satisfied.

For example, when a command or request for the test operation is received from the external device through the pad 210 and the receiver 220, the controller 240 may detect that the test condition is satisfied.

The controller 240 may receive temperature information indicating an ambient temperature from the temperature sensor TES (refer to FIG. 1). The controller 240 may divide and manage an entire temperature range to which the electronic device 200 is capable of belonging or the entire temperature range which the temperature sensor TES is capable of sensing into a plurality of temperature ranges. When a temperature range to which the electronic device 200 belongs changes, the controller 240 may detect that the test condition is satisfied.

The controller 240 may divide and manage the entire voltage range in which the electronic device 200 is capable of operating into a plurality of voltage ranges. When a voltage range to which the electronic device 200 belongs changes, the controller 240 may detect that the test condition is satisfied. In an embodiment, the entire voltage range may be defined based on a standard associated with the electronic device 200.

When it is detected that the test condition is satisfied, the controller 240 may control the BIST circuit 224 and the tester circuit 230 such that the test operation is performed. In operation S120, the controller 240 may select the pattern signal PS. For example, depending on a given test policy, the controller 240 may control the pattern generator 232 by using the third register R3 such that one of pattern signals which the pattern generator 232 is capable of generating may be generated.

In operation S130, the electronic device 200 may select the jitter signal JS. For example, depending on a given test policy, the controller 240 may select one of frequencies of pattern signals, which the pattern generator 232 is capable of generating, and one of amplitudes of the pattern signals and may control the jitter generator 233 by using the fourth register R4 such that the jitter signal JS corresponding to the selected frequency and the selected amplitude is generated.

In operation S140, the electronic device 200 may generate the test signal TS. The adder 234 may sum up the pattern signal PS and the jitter signal JS to generate the test signal TS.

In operation S150, the electronic device 200 may receive the test signal TS. For example, the receiver 220 of the electronic device 200 may receive the test signal TS, for example, a serialized test signal from the tester circuit 230.

In operation S160, the electronic device 200 may record pass or fail information. The BIST circuit 224 may check the number of error bits or the bit error rate. When the number of error bits or the bit error rate is less than the threshold value, the BI ST circuit 224 may output the pass information to the controller 240. When the number of error bits or the bit error rate is equal to or greater than the threshold value, the BIST circuit 224 may output the fail information to the controller 240. The controller 240 may record the pass information or the fail information in the memory 241.

In operation S170, the electronic device 200 may determine whether a current jitter signal JS is the last jitter signal JS. For example, the electronic device 200 may determine whether all the combinations of frequencies and amplitudes of the selectable jitter signal JS are selected for the test operation. When it is determined that at least one of all the combinations is not selected, in operation S130, the electronic device 200 may select any other combination, which is not yet selected, and may continue the test operation. In an embodiment, operation S130, operation S140, operation S150, and operation S160 may be a plurality of test loops for one pattern signal.

When it is determined that all the combinations are selected, the electronic device 200 may perform operation S180. In operation S180, the electronic device 200 may determine whether a current pattern signal PS is the last pattern signal PS. For example, the electronic device 200 may determine all of a plurality of pattern signals which the pattern generator 232 is capable of generating are selected for the test operation. When it is determined that at least one of all the pattern signals is not selected, in operation S120, the electronic device 200 may select any other pattern signal, which is not yet selected, and may continue the test operation.

When it is determined that all the pattern signals are selected, the electronic device 200 may perform operation S190. In operation S190, the electronic device 200 may perform a post operation by using the recorded information.

In an embodiment, the controller 240 may have a first mode of storing a result of a latest test operation and a second mode of storing the result of the latest test operation and a result of a previous test operation. The first mode and the second mode may be set by the external device. In the second mode, a number of results of test operations to be maintained by the controller 240 may be set by the external device.

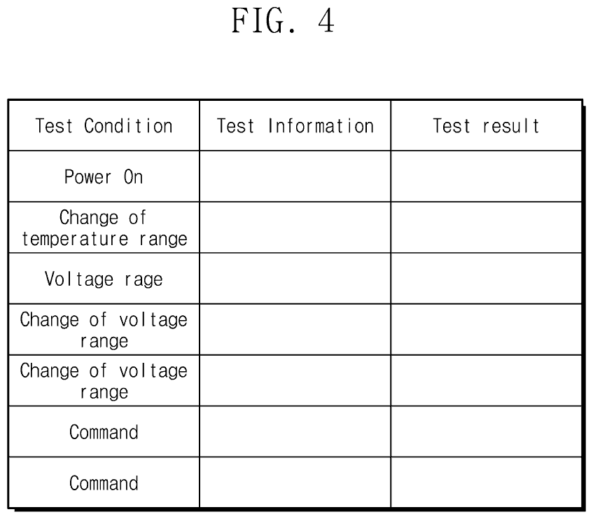

FIG. 4 illustrates an example of test results of test operations according to one or more example embodiments of the disclosure. The test results may be stored by the controller 240 in the memory 241. Referring to FIGS. 2 and 4, in each test operation, the controller 240 may write a test condition causing a corresponding test operation in association with a test result of the corresponding test operation. For example, the test condition causing the test operation may include power-on, a change in a temperature range, a change in a voltage range, and a command for a test operation.

In each test operation, the controller 240 may record test information and a comparison result as a test result. The comparison result may be a result of comparison between the pattern signal PS and the internal signal IC. The test information may include information affecting the test operation in the process of performing the test operation. The comparison result may include pass information or fail information. For example, each test operation may include a plurality of test loops. Each of the plurality of test loops may include test information and a comparison result. That is, each test operation may include a plurality of test information and a plurality of comparison results.

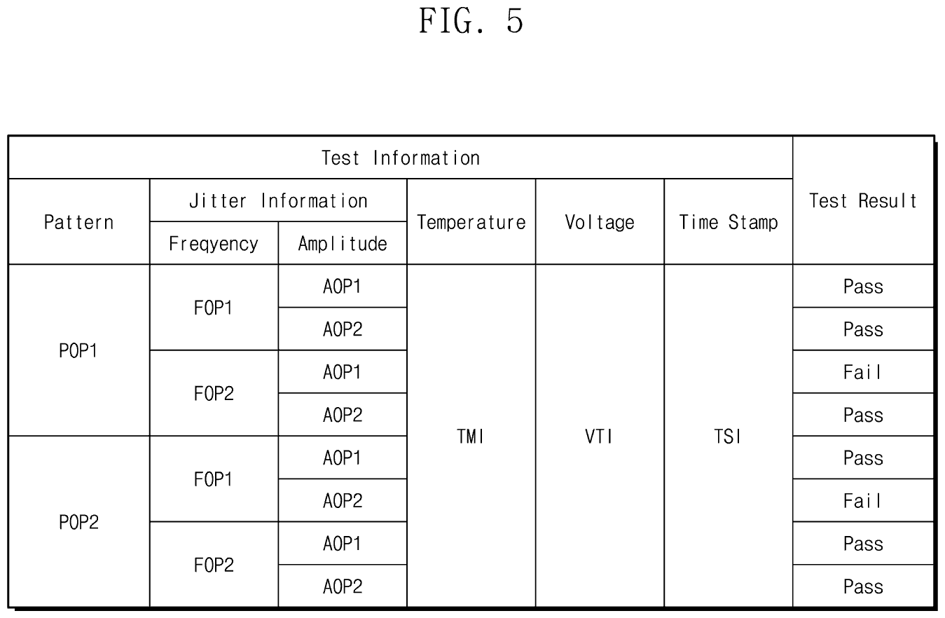

FIG. 5 illustrates an example of a test result and a comparison result associated with one test operation. Referring to FIGS. 2, 3, and 5, a test result may include test information and a comparison result. The test information may include information affecting the test operation in the process of performing the test operation. The comparison result may include a result of comparing the pattern signal PS and the internal signal IC.

The electronic device 200 may perform the test operation by using a first pattern signal POP1 and a second pattern signal POP2 and may record a test result based thereon. The electronic device 200 may record information for identifying the first pattern signal POP1 and the second pattern signal POP2 as test information of the test result. However, a number of pattern signals on which the electronic device 200 performs the test operation is not limited.

The electronic device 200 may perform the test operation on each of the first pattern signal POP1 and the second pattern signal POP2 by using a first frequency FOP1 and a second frequency FOP2 of the jitter signal JS and may record test results based thereon. The electronic device 200 may record information for identifying the first frequency FOP1 and the second frequency FOP2 as test information of the test result. However, a number of frequencies of the jitter signal JS on which the electronic device 200 performs the test operation is not limited.

The electronic device 200 may perform the test operation on each of the first frequency FOP1 and the second frequency FOP2 of the jitter signal JS by using a first amplitude AOP1 and a second amplitude AOP2 and may record test results based thereon. The electronic device 200 may record information for identifying the first amplitude AOP1 and the second amplitude AOP2 as test information of the test result. However, a number of amplitudes of the jitter signal JS on which the electronic device 200 performs the test operation is not limited.

The electronic device 200 may record ambient environment information as test information of the test operation. For example, the electronic device 200 may record temperature information TMI, voltage information VTI, and time stamp information TSI, which are obtained in the process of performing the test operation, as test information of the test operation. The temperature information TMI may be obtained by using the temperature sensor TES (refer to FIG. 1). The voltage information VTI may be obtained by using a circuit associated with power of the electronic device 200.

The time stamp information TSI may include information about an order of performing the test operation. For example, the electronic device 200 may record information capable of identifying a time point sequence of the collected test results (e.g., each point in time when each test result is collected) as the time stamp information TSI. For example, the time stamp information TSI may include a plurality of bits, and the plurality of bits may have circulated values. A smallest value and a greatest value among the circulated values may correspond to an oldest test result and a latest test result, respectively.

The electronic device 200 may record pass information or fail information as a test result for each comparison result, with respect to each pattern signal, for each frequency of the jitter signal JS, and for each amplitude of the jitter signal JS.

The electronic device 200 may perform the test operation by using various test patterns of the pattern signal PS, various frequencies of the jitter signal JS, and various amplitudes of the jitter signal JS and may record a test result. Accordingly, the jitter-tolerance JTOL of the electronic device 200 may be detected by the electronic device 200 in detail without the support of the external device.

The electronic device 200 may further record a test result with respect to the temperature information TMI, the voltage information VTI, and the time stamp information TSI. Accordingly, the jitter-tolerance JTOL of the electronic device 200 according to a temperature, a voltage, and a time may be detected by the electronic device 200 in detail without the support of the external device.

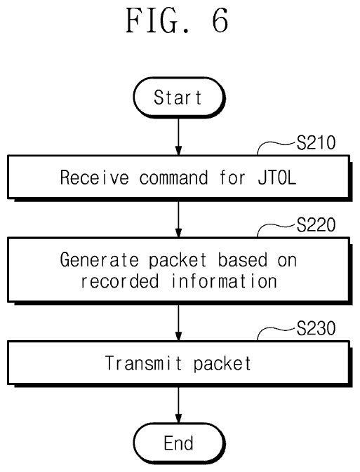

FIG. 6 illustrates an example in which the electronic device 200 performs a post operation (refer to operation S190 of FIG. 3) according to one or more example embodiments of the disclosure. Referring to FIGS. 2 and 6, the electronic device 200 may receive a command for the jitter-tolerance JTOL. For example, the electronic device 200 may receive information of the jitter-tolerance JTOL, that is, a command for requesting the test result from the external device through the pad 210 and the receiver 220. For example, the command may include information for identifying whether to request the latest test result or whether to request the collected test results.

In operation S220, the electronic device 200 may generate a packet based on the recorded information. For example, the controller 240 of the electronic device 200 may generate a packet including a test result or test results requested by the command. The packet may include information for identifying how many test results are included.

In operation S230, the electronic device 200 may transmit the packet. For example, the controller 240 of the electronic device 200 may transmit the packet to the external device by using the transmitter TX (refer to FIG. 1).

As the electronic device 200 collects test results and transmits the test results to the external device in response to the command of the external device, the external device may easily collect information of the jitter-tolerance JTOL of the electronic device 200. In particular, even if the manufacturing environment of the electronic device 200 changes, the electronic device 200 may internally perform the test operation and may record a test result. Accordingly, the change in the jitter-tolerance JTOL according to the change in the manufacturing environment of the electronic device 200 may be obtained. Accordingly, the accuracy of determining the electronic device 200 as good or bad may be further improved, and it may be possible to improve the manufacturing environment of the electronic device 200.

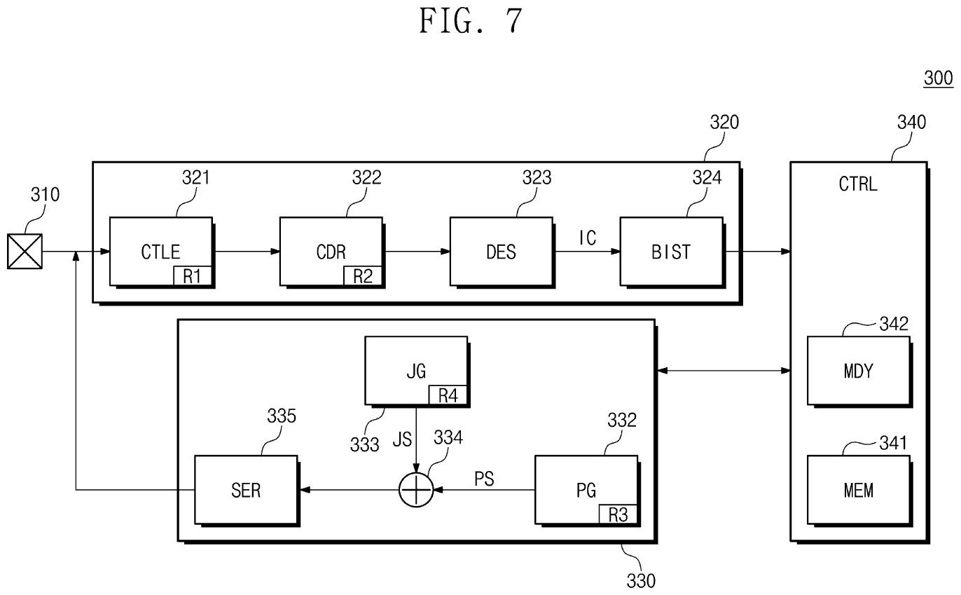

FIG. 7 is a diagram illustrating an electronic device 300 according to one or more example embodiments of the disclosure. In an embodiment, the electronic device 300 may correspond to the first electronic device 110 or the second electronic device 120 of FIG. 1. Referring to FIGS. 1 and 7, the electronic device 300 may include a pad 310, a receiver 320, a tester circuit 330, and a controller (CTRL) 340. In an embodiment, the receiver 320 may correspond to the receiver RX described with reference to FIG. 1. The temperature sensor TES illustrated in FIG. 1 may be included in a component of the electronic device 300 although not separately illustrated in FIG. 7.

The pad 310 may be connected to an external device, for example, the first electronic device 110 or the second electronic device 120. The receiver 320 may receive a signal from the external device through the pad 310 or may receive a signal from the tester circuit 330. The receiver 320 may include a continuous time linear equalization (CTLE) circuit 321, a clock and data recovery (CDR) circuit 322, a deserialization (DES) circuit 323, and a built-in self-test (BIST) 324. Configurations and operations of the CTLE circuit 321, the CDR circuit 322, the DES circuit 323, and the reception circuit 324 may be the same or similar to the configurations and the operations of the CTLE circuit 221, the CDR circuit 222, the DES circuit 223, and the BIST circuit 224 described with reference to FIG. 2. Thus, additional description will be omitted to avoid redundancy.

The tester circuit 330 may test the jitter-tolerance JTOL of the receiver 320. The tester circuit 330 may include a pattern generator 332, a jitter generator 333, an adder 334, and a serialization (SER) circuit 335. Configurations and operations of the pattern generator 332, the jitter generator 333, the adder 334, and the SER circuit 335 may be the same or similar to the configurations and the operations of the pattern generator 232, the jitter generator 233, the adder 234, and the SER circuit 235 described with reference to FIG. 2. Thus, additional description will be omitted to avoid redundancy.

When the communication with the external device is made, the tester circuit 330 may be deactivated. The receiver 320 may filter a signal received from the external device through the pad 310, to be transferred to the controller 340.

When the communication with the external device is not made, the tester circuit 330 may perform the test operation. The tester circuit 330 may transfer the test signal TS to the receiver 320. The receiver 320 may filter the test signal TS to generate the internal signal IC. The BIST circuit 324 may detect a number of error bits or a bit error rate in the internal signal IC. When the number of error bots or the bit error rate is less than a threshold value, the BIST circuit 324 may determine “PASS”. When the number of error bits or the bit error rate is equal to or greater than the threshold value, the BIST circuit 324 may determine “FAIL”. The BIST circuit 324 may transfer a pass or fail result to the controller 340. In other words, when the pattern signal PS and the internal signal IC coincide with each other, the BIST circuit 324 is configured to output pass information as a comparison result, and when the pattern signal PS and the internal signal IC do not coincide with each other, the BIST circuit 324 is configured to output fail information as the comparison result.

In an embodiment, the controller 340 may select a plurality of test loops in one test operation. In each test loop, the controller 340 may select a kind of the pattern signal PS, a frequency of the jitter signal j S, and amplitude of the jitter signal JS. That is, during one test operation, the BIST circuit 324 may provide the controller 340 with pieces of pass information or fail information about various test signals TS.

When the test operation is not performed, the controller 340 may receive a communication signal from the external device through the receiver 320. In the test operation, the controller 340 may receive comparison results (or test results), that is, pieces of pass or fail information from the tester circuit 330. The controller 340 may store the communication signal or the communication results in a memory (MEM) 341. For example, the memory 341 may include a random access memory such as an SRAM, a DRAM, an MRAM, a PRAM, an FRAM, or an RRAM.

The controller 340 may perform a post operation, based on a test result stored in the memory 341. In an embodiment, the controller 340 may further include an optimizer MDY 342 configured to perform the optimization operation as a post operation. The optimizer MDY 342 may be configured to internally optimize the jitter-tolerance JTOL of the electronic device 300.

In an embodiment, the electronic device 300 may be implemented with a storage device. The controller 340 may be configured to access an additionally provided nonvolatile memory device in addition to a reception operation through the receiver 320 and the test operation through the tester circuit 330.

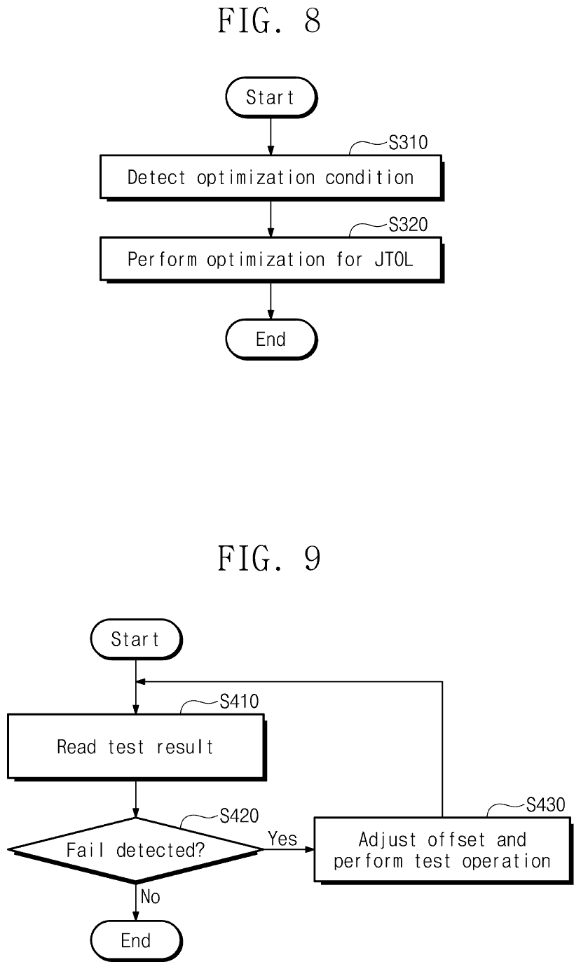

FIG. 8 illustrates an operating method of the electronic device 300 according to one or more example embodiments of the disclosure. Referring to FIGS. 7 and 8, in operation S310, the electronic device 300 may detect an optimization condition. For example, the controller 340 of the electronic device 300 may detect whether the optimization condition is satisfied. For example, when the fail is detected in the test operation, when the electronic device 300 is powered on, when a temperature range to which the electronic device 300 belongs changes, when a voltage range to which the electronic device 300 belongs changes, and/or when a command for the optimization operation is received, the optimization condition may be satisfied. In an embodiment, whether to perform the optimization operation as a post operation may be activated or deactivated by the external device.

In an embodiment, even if the optimization condition is satisfied, when the electronic device 300 is communicating with the external device, the electronic device 300 may delay the optimization operation. As another example, when the optimization condition is satisfied, the electronic device 300 may notify the external device that the optimization operation is required and may stop the communication with the external device to perform the optimization operation.

FIG. 9 illustrates an example in which the electronic device 300 performs the optimization operation, according to one or more example embodiments of the disclosure. Referring to FIGS. 7 and 9, in operation S410, the electronic device 300 may read a test result. For example, the controller 340 may read the latest test result stored in the memory 341.

In operation S420, the electronic device 300 may determine whether the fail is detected. For example, the electronic device 300 may determine whether the read test result includes fail information. When the test result does not include the fail information, the controller 340 may terminate the optimization operation without an additional operation.

When the test result includes the fail information, in operation S430, the electronic device 300 may adjust an offset and may perform the test operation. For example, the controller 340 may adjust a characteristic of the receiver 320 by adjusting at least one of an offset stored in the third register R3 and an offset stored in the fourth register R4. The tester circuit 330 may perform the test operation on the receiver 320 having the adjusted offset and may transfer the test result to the controller 340. The controller 340 may store the test result in the memory 341. Afterwards, the controller 340 may again perform operation S410.

In an embodiment, the adjustment of the offset may be performed based on a preset offset adjustment policy. According to the offset adjustment policy, a current adjustment direction and a current adjustment amount may be determined depending on a current offset value, a previous adjustment direction (e.g., an increase or a decrease), and/or an adjustment amount. In an embodiment, the offset adjustment policy may be experimentally defined or may be an inference model based on machine learning.

As described above, in the optimization operation, the electronic device 300 may repeat the test operation while adjusting the offset of the receiver 320 until the pass is determined in association with (or in association with all of) the patterns of the pattern signal PS, the frequencies of the jitter signal JS, and the amplitudes of the jitter signal JS. Accordingly, the jitter-tolerance JTOL of the electronic device 300 may be improved by the optimization operation.

In an embodiment, the optimization operation may be performed in the process of manufacturing the electronic device 300 or while the electronic device 300 is being used in an electronic system equipped with the electronic device 300. Whether to perform the optimization operation may be activated or deactivated by the electronic system.

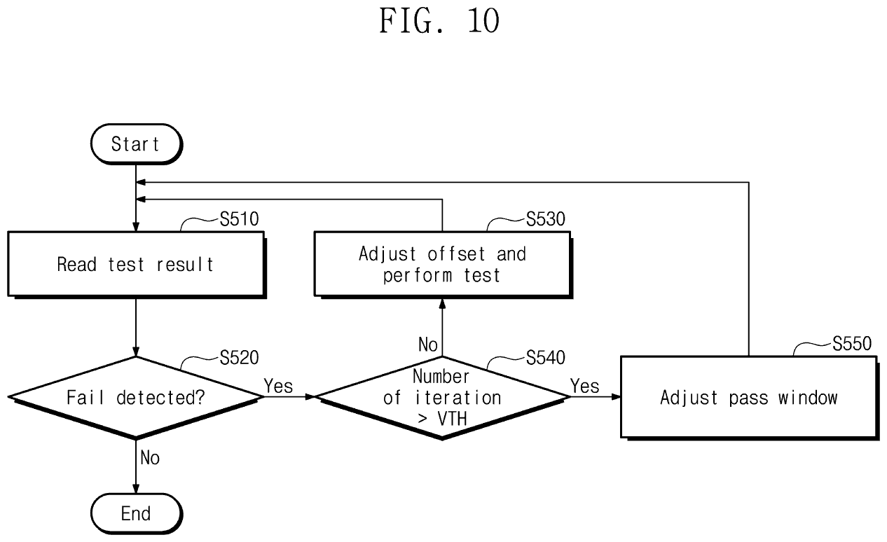

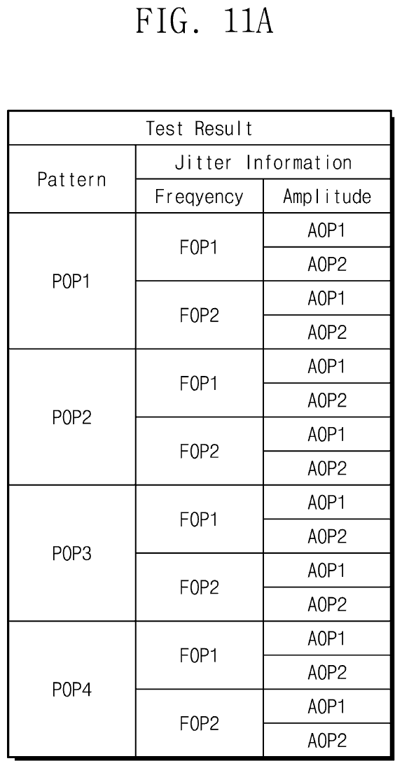

FIG. 10 illustrates another example in which the electronic device 300 performs the optimization operation, according to one or more example embodiments of the disclosure. Referring to FIGS. 7 and 10, in operation S510, the electronic device 300 may read a test result. For example, the controller 340 may read the latest test result stored in the memory 341.

In operation S520, the electronic device 300 may determine whether the fail is detected. For example, the electronic device 300 may determine whether the read test result includes fail information. When the test result does not include the fail information, the controller 340 may terminate the optimization operation without an additional operation.

When the test result includes the fail information, in operation S530, the electronic device 300 may determine a number of times of iteration is greater than a threshold value VTH. For example, the controller 340 may determine whether the number of test operations repeated in the optimization operation is greater than the threshold value VTH.

When the number of repeated test operations is not greater than the threshold value VTH, in operation S540, the electronic device 300 may adjust an offset and may perform the test operation. For example, the controller 340 may adjust a characteristic of the receiver 320 by adjusting at least one of an offset stored in the third register R3 and an offset stored in the fourth register R4. The tester circuit 330 may perform the test operation on the receiver 320 having the adjusted offset and may transfer the test result to the controller 340. The controller 340 may store the test result in the memory 341. Afterwards, the controller 340 may again perform operation S510.

When the number of repeated test operations is greater than the threshold value VTH, in operation S550, the electronic device 300 may adjust a pass window. For example, the pass window may indicate a range of test loops which should be determined as “PASS” to complete the optimization operation. When the optimization operation is initiated, the pass window may be defined by all the pattern signals, all the frequencies of the jitter signal JS, and all the amplitudes of the jitter signal JS. When the number of repeated test operations is greater than the threshold value VTH, the controller 340 may exclude at least one of the pattern signals, at least one of the frequencies of the jitter signal JS, and at least one of the amplitudes of the jitter signal JS from the pass window. Afterwards, the controller 340 may again perform operation S510.

As described above, in the optimization operation, when the test operation is repeated as much as the threshold value VTH, the electronic device 300 may reduce the pass window for the completion of the optimization operation. Accordingly, when the electronic device 300 is being used in the electronic system equipped with the electronic device 300, the optimization operation may be prevented from consuming an excessively long time. In an embodiment, the threshold value VTH may be defined by the electronic system. The threshold value VTH may be set to a multi-step threshold value, and the pass window may be stepwise decreased through the multi-step threshold value.

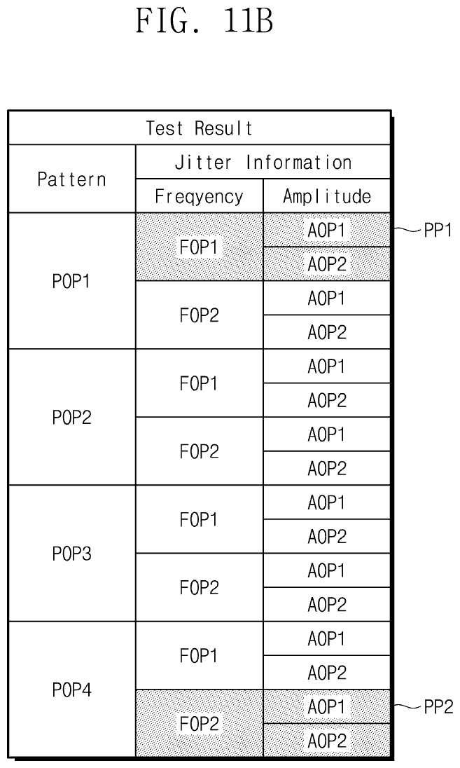

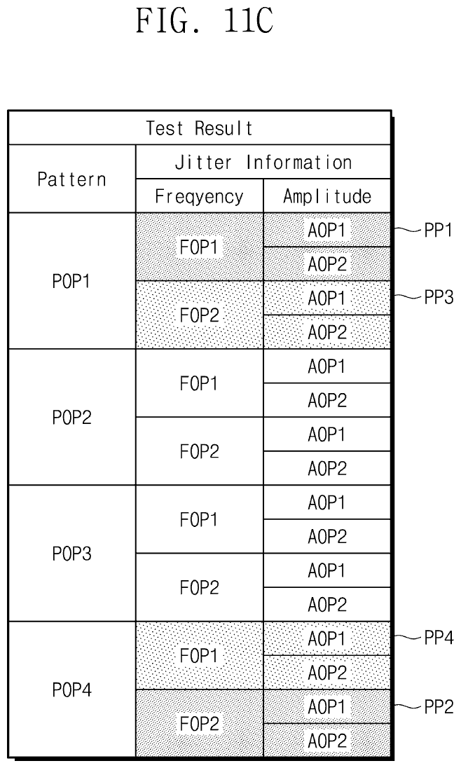

FIG. 11A illustrates an example of an initial state of a pass window according to one or more example embodiments of the disclosure. Referring to FIGS. 7, 10, and 11A, in an initial state, the pass window may include all the test loops. For example, the pass window may include test loops for the first pattern signal POP1, the second pattern signal POP2, a third pattern signal POP3, and a fourth pastern signal POP4. The pass window may include the first frequency FOP1 and the second frequency FOP2 of the jitter signal JS, for respective pattern signals including the first pattern signal POP1, the second pattern signal POP2, the third pattern signal POP3, and the fourth pastern signal POP4. The pass window may include the first amplitude AOP1 and the second amplitude AOP2 of the jitter signal JS, for respective frequencies including the first frequency FOP1 and the second frequency FOP2 of the jitter signal JS.

FIG. 11B illustrates an example in which a pass window is reduced according to one or more example embodiments of the disclosure. Referring to FIGS. 7, 11A, and 11B, the electronic device 300 may exclude test loops, which correspond to a first pass point PP1 corresponding to the first pattern signal POP1 and the first frequency FOP1 of the jitter signal JS and a second pass point PP2 corresponding to the fourth pastern signal POP4 and the second frequency FOP2 of the jitter signal JS, from the pass window.

In an embodiment, the first pass point PP1 and the second pass point PP2 may correspond to test loops corresponding to a jitter signal with a lowest occurrence probability from among the test loops. For example, the first pass point PP1 and the second pass point PP2 may correspond to test loops corresponding to a worst case, in which an influence of the jitter signal JS is strongest, from among the test loops.

In an embodiment, an example in which the pass window is adjusted in a unit of the frequency of the jitter signal JS is described, but the pass window may be adjusted in a unit of the pattern signal or in a unit of the amplitude of the jitter signal JS.

FIG. 11C illustrates an example in which a pass window is additionally reduced according to one or more example embodiments. Referring to FIGS. 7, 11A, 11B, and 11C, after the test loops corresponding to the first pass point PP1 and the second pass point PP2 have been excluded, and the optimization operation is again repeated, the electronic device 300 may further exclude test loops, which correspond to a third pass point PP3 corresponding to the first pattern signal POP1 and the second frequency FOP2 of the jitter signal JS, and a fourth pass point PP4 corresponding to the fourth pastern signal POP4 and the first pattern signal POP1 of the jitter signal JS, from the pass window.

In an embodiment, the third pass point PP3 and the fourth pass point PP4 may correspond to test loops corresponding to a jitter signal with a lowest occurrence probability from among the test loops remaining in the pass window (that is, remaining test loops excluding the first pass point PP1 and the second pass point PP2). For example, the third pass point PP3 and the fourth pass point PP4 may correspond to test loops corresponding to a worst case, in which the influence of the jitter signal JS is strongest, from among the remaining test loops in the pass window.

In an embodiment, an example in which the pass window is adjusted in a unit of the frequency of the jitter signal JS is described, but the pass window may be adjusted in a unit of the pattern signal or in a unit of the amplitude of the jitter signal JS.

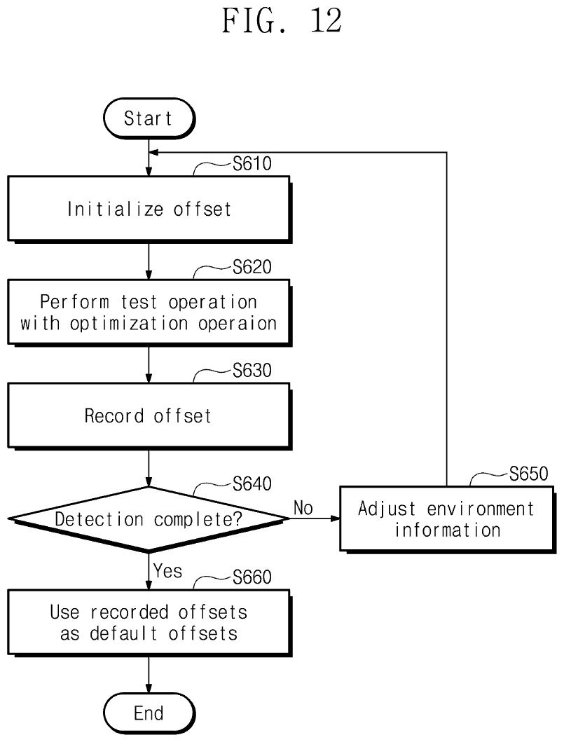

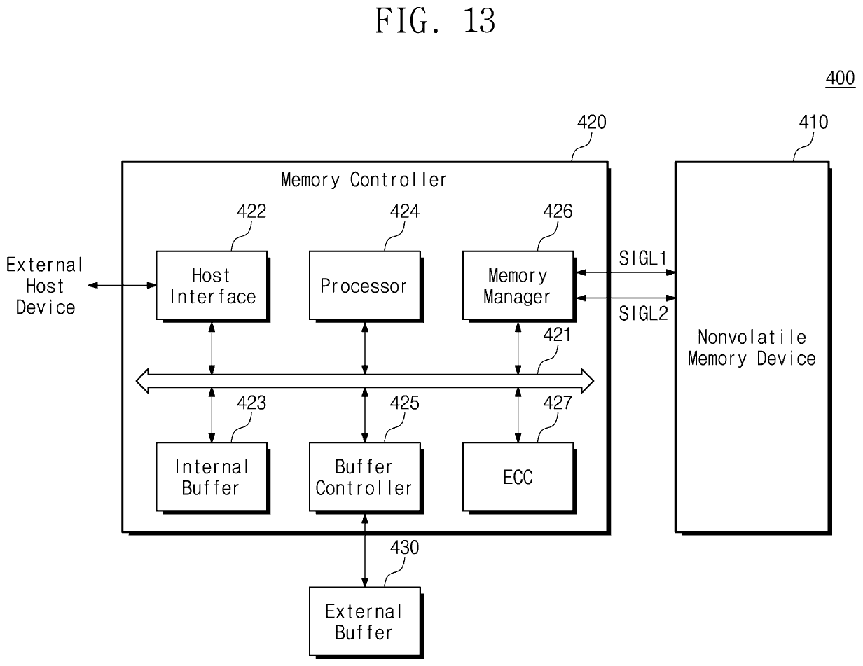

FIG. 12 illustrates another example of an operating method of the electronic device 300 according to one or more example embodiments of the disclosure. In an embodiment, an example of an offset detection operation of detecting default offsets is illustrated in FIG. 12. Referring to FIGS. 7 and 12, in operation S610, an electronic device 300 may initialize an offset. For example, the controller 340 may initialize the offset of the third register R3 and the offset of the fourth register R4.

In operation S620, the electronic device 300 may perform the test operation together with the optimization operation. For example, the controller 340 may perform the test operation based on current environment information such as temperature and voltage and may perform the optimization operation when (e.g., adjusting at least one of an offset stored in the third register R3 and an offset stored in the fourth register R4). In an embodiment, the optimization operation is performed when an optimization condition is satisfied.

In operation S630, the electronic device 300 may record an offset (e.g., adjusted offset). For example, the controller 340 may record the offset of the third register R3 and the offset of the fourth register R4 obtained through the optimization operation, as an offset associated with the current environment information.

In operation S640, the electronic device 300 may determine whether the detection is completed. For example, the controller 340 may determine whether an offset detection operation on different environment information is completed. For example, the different environment information may include temperature ranges or voltage ranges to which the electronic device 300 may belong.

When the offset detection operation is not completed, in operation S650, the electronic device 300 may adjust environment information. For example, the controller 340 may request the external device to adjust the temperature range or the voltage range of the electronic device 300. Depending on a request of the controller 340, the external device may adjust a temperature range to which the electronic device 300 belongs or a voltage range of a voltage which is supplied to the electronic device 300. Afterwards, the electronic device 300 may again perform operation S620.

When the offset detection operation is completed, in operation S660, the electronic device 300 may use the recorded offsets as default offsets. For example, in a specific temperature range and a specific voltage range, the controller 340 may record a default offset corresponding to the specific temperature range and the specific voltage range in the third register R3 or the fourth register R4. When the temperature range or the voltage range changes, the controller 340 may record a default offset corresponding to the changed temperature range or voltage range in the third register R3 or the fourth register R4. Accordingly, the receiver 320 may have the jitter-tolerance JTOL which is optimized adaptively to the environment information (e.g., a temperature range or a voltage range).

FIG. 13 illustrates a storage device 400 according to one or more example embodiments of the disclosure. In an embodiment, the storage device 400 may correspond to the electronic device 200 of FIG. 2 or the electronic device 300 of FIG. 7. Referring to FIG. 13, the storage device 400 may include a nonvolatile memory device 410, a memory controller 420, and an external buffer 430. The nonvolatile memory device 410 may include a plurality of memory cells. Each of the plurality of memory cells may store two or more bits.

For example, the nonvolatile memory device 410 may include at least one of various nonvolatile memory devices such as a flash memory device, a phase-change memory device, a ferroelectric memory device, a magnetic memory device, and a resistive memory device.

The memory controller 420 may correspond to the pad 210, the receiver 220, the tester circuit 230, and the controller 240 of FIG. 2 or may correspond to the pad 310, the receiver 320, the tester circuit 330, and the controller 340 of FIG. 7. The memory controller 420 may receive, from an external host device, various requests for writing data in the nonvolatile memory device 410 or reading data from the nonvolatile memory device 410. The memory controller 420 may store (or buffer) user data communicated with the external host device in the external buffer 430 and may store metadata for managing the storage device 400 in the external buffer 430.

The memory controller 420 may access the nonvolatile memory device 410 through first signal lines SIGL1 and second signal lines SIGL2. For example, the memory controller 420 may transmit a command and an address to the nonvolatile memory device 410 through the first signal lines SIGL1. The memory controller 420 may exchange data with the nonvolatile memory device 410 through the first signal lines SIGL1.

The memory controller 420 may transmit a first control signal to the nonvolatile memory device 410 through the second signal lines SIGL2. The memory controller 420 may receive a second control signal from the nonvolatile memory device 410 through the second signal lines SIGL2.

In an embodiment, the memory controller 420 may be configured to control two or more nonvolatile memory devices. The memory controller 420 may provide the first signal lines SIGL1 and the second signal lines SIGL2 independently for each of the two or more nonvolatile memory devices.

As another example, the memory controller 420 may be configured such that two or more nonvolatile memory devices share the first signal lines SIGL1. The memory controller 420 may be configured such that the two or more nonvolatile memory devices share some of the second signal lines SIGL2 and the others thereof are separately provided.

The external buffer 430 may include a random access memory. For example, the external buffer 430 may include at least one of a dynamic random access memory, a phase-change random access memory, a ferroelectric random access memory, a magnetic random access memory, and a resistive random access memory.

The memory controller 420 may include a bus 421, a host interface 422, an internal buffer 423, a processor 424, a buffer controller 425, a memory manager 426, and an error correction code (ECC) block 427.

The bus 421 may provide communication channels between components of the memory controller 420. The host interface 422 may receive various requests from the external host device and may parse the received requests. The host interface 422 may store the parsed requests in the internal buffer 423.

The host interface 422 may transmit various responses to the external host device. The host interface 422 may exchange signals with the external host device in compliance with a given communication protocol. The internal buffer 423 may include a random access memory. For example, the internal buffer 423 may include a static random access memory or a dynamic random access memory. In an embodiment, the host interface 422 may correspond to the pad 210, the receiver 220, and the tester circuit 230 described with reference to FIG. 2 or may correspond to the pad 310, the receiver 320, and the tester circuit 330 described with reference to FIG. 7.

The processor 424 may execute an operating system or firmware for driving the memory controller 420. The processor 424 may read the parsed requests stored in the internal buffer 423 and may generate addresses and commands for controlling the nonvolatile memory device 410. The processor 424 may provide the generated commands and addresses to the memory manager 426.

The processor 424 may store various metadata for managing the storage device 400 in the internal buffer 423. The processor 424 may access the external buffer 430 through the buffer controller 425. The processor 424 may control the buffer controller 425 and the memory manager 426 such that user data stored in the external buffer 430 are provided to the nonvolatile memory device 410.

The processor 424 may control the host interface 422 and the buffer controller 425 such that the data stored in the external buffer 430 are provided to the external host device. The processor 424 may control the buffer controller 425 and the memory manager 426 such that the data received from the nonvolatile memory device 410 are stored in the external buffer 430. The processor 424 may control the host interface 422 and the buffer controller 425 such that the data received from the external host device are stored in the external buffer 430.

In an embodiment, the processor 424 and the internal buffer 423 may correspond to the controller 240 described with reference to FIG. 2 or may correspond to the controller 340 described with reference to FIG. 7. The internal buffer 423 may correspond to the memory 241 or 341 of the controller 240 or 340.

Under control of the processor 424, the buffer controller 425 may write data in the external buffer 430 or may read data from the external buffer 430. The memory manager 426 may communicate with the nonvolatile memory device 410 through the first signal lines SIGL1 and the second signal lines SIGL2 under control of the processor 424.

The memory manager 426 may access the nonvolatile memory device 410 under control of the processor 424. For example, the memory manager 426 may access the nonvolatile memory device 410 through the first signal lines SIGL1 and the second signal lines SIGL2. The memory manager 426 may communicate with the nonvolatile memory device 410, based on a protocol defined in compliance with the standard or defined by a manufacturer.

The error correction code block 427 may perform error correction encoding for data to be provided to the nonvolatile memory device 410 by using the error correction code ECC. The error correction code block 427 may perform error correction decoding for data received from the nonvolatile memory device 410 by using the error correction code ECC.

In an embodiment, the external buffer 430 and the buffer controller 425 may be omitted in the storage device 400. When the external buffer 430 and the buffer controller 425 are omitted, the functions which are described as being performed by the external buffer 430 and the buffer controller 425 may be performed by the internal buffer 423.

The storage device 400 may internally measure and record the jitter-tolerance JTOL of the receiver 220 or 320 of the host interface 422 by performing the test operation. In an embodiment, the storage device 400 may measure and record the jitter-tolerance JTOL over time. The storage device 400 may provide test results of the jitter-tolerance JTOL to the external host device depending on a request of the external host device.

The storage device 400 may perform the optimization operation based on the test result. The storage device 400 may adjust an offset of the receiver 220 or 320 of the host interface 422 by performing the optimization operation, and thus, the jitter-tolerance JTOL may be improved.

The storage device 400 may store default offset information of the receiver 220 or 320 of the host interface 422 according to environment information. When the environment information changes, the storage device 400 may change the default offset of the receiver 220 or 320 of the host interface 422. Accordingly, the jitter-tolerance JTOL of the storage device 400 may be improved.

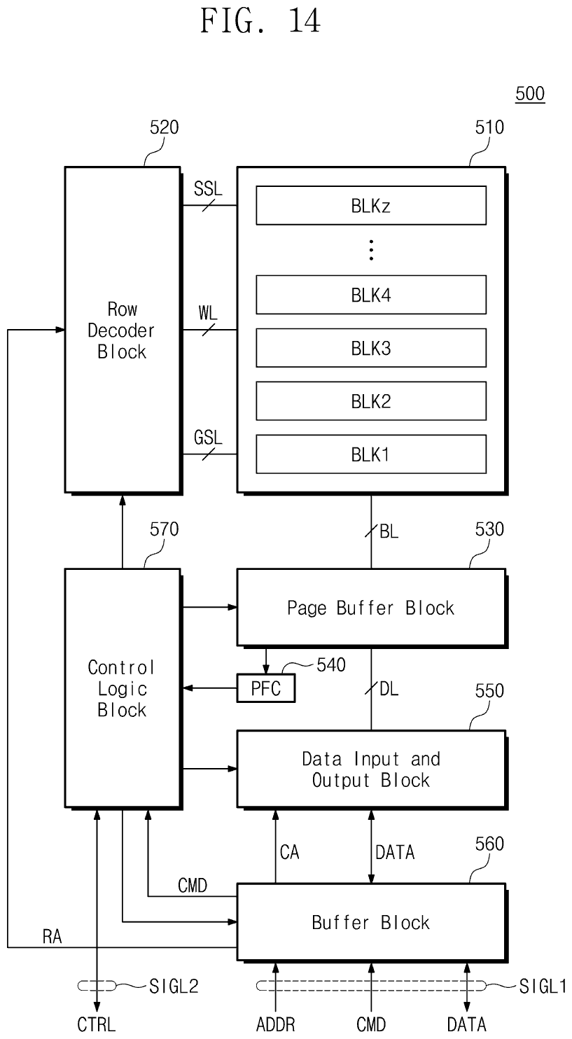

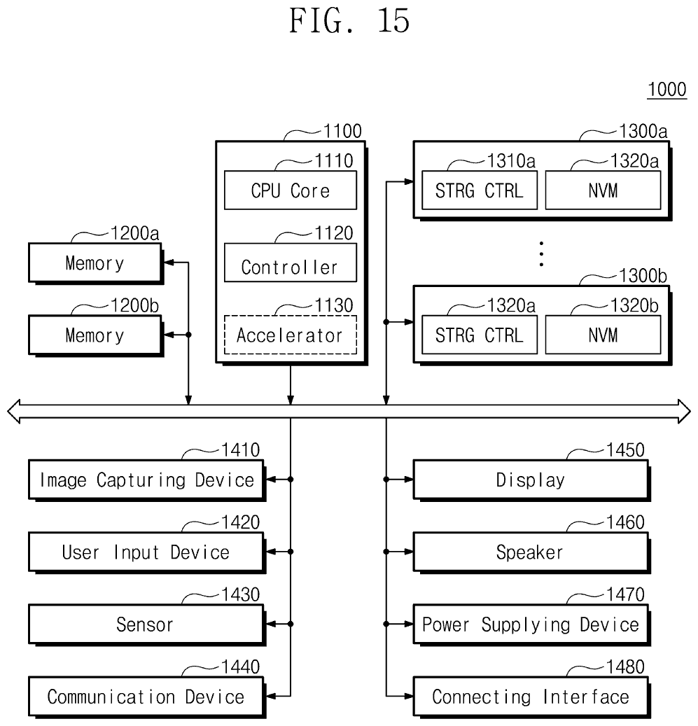

FIG. 14 is a block diagram illustrating a nonvolatile memory device 500 according to one or more example embodiments of the disclosure. Referring to FIG. 14, the nonvolatile memory device 500 may include a memory cell array 510, a row decoder block 520, a page buffer block 530, a pass/fail check block (PFC) 540, a data input and output block 550, a buffer block 560, and a control logic block 570.

The memory cell array 510 may include a plurality of memory blocks BLK1 to BLKz. Each of the memory blocks BLK1 to BLKz may include a plurality of memory cells. Each of the memory blocks BLK1 to BLKz may be connected to the row decoder block 520 through at least one ground selection line GSL, word lines WL, and at least one string selection line SSL. Some of the word lines WL may be used as dummy word lines. Each of the memory blocks BLK1 to BLKz may be connected to the page buffer block 530 through a plurality of bit lines BL. The plurality of memory blocks BLK1 to BLKz may be connected in common to the plurality of bit lines BL.

In an embodiment, each of the plurality of memory blocks BLK1 to BLKz may correspond to a unit of an erase operation. Memory cells belonging to each memory block may be erased at the same time. As another example, each of the memory blocks BLK1 to BLKz may be divided into a plurality of sub-blocks. Each of the plurality of sub-blocks may correspond to a unit of the erase operation.

The row decoder block 520 may be connected to the memory cell array 510 through the ground selection lines GSL, the word lines WL, and the string selection lines SSL. The row decoder block 520 may operate under control of the control logic block 570.

The row decoder block 520 may decode a row address RA received from the buffer block 560 and may control voltages to be applied to the string selection lines SSL, the word lines WL, and the ground selection lines GSL based on the decoded row address.

The page buffer block 530 may be connected to the memory cell array 510 through the plurality of bit lines BL. The page buffer block 530 may be connected to the data input and output block 550 through a plurality of data lines D L. The page buffer block 530 operates under control of the control logic block 570.

In a program operation, the page buffer block 530 may store data to be written in memory cells. The page buffer block 530 may apply voltages to the plurality of bit lines BL based on the stored data. In a read operation or in a verify read operation that is performed in the program operation or the erase operation, the page buffer block 530 may sense voltages of the bit lines BL and may store a sensing result.

In the verify read operation associated with the program operation or the erase operation, the pass/fail check block 540 may verify the sensing result of the page buffer block 530. For example, in the verify read operation which is performed in the program operation, the pass/fail check block 540 may count a number of a value (e.g., a number of ‘0’) corresponding to a number of on-cells which are not programmed to a target threshold voltage or higher.

In the verify read operation which is performed in the erase operation, the pass/fail check block 540 may count a number of a value (e.g., a number of ‘1’s) corresponding to a number of off-cells which are not erased to a target threshold voltage or lower. When a counting result is greater than or equal to a threshold value, the pass/fail check block 540 may output a fail signal to the control logic block 570. When the counting result is smaller than the threshold value, the pass/fail check block 540 may output a pass signal to the control logic block 570. Depending on the verification result of the pass/fail check block 540, a program loop of the program operation may be further performed, or an erase loop of the erase operation may be further performed.

The data input and output block 550 may be connected to the page buffer block 530 through the plurality of data lines DL. The data input and output block 550 may receive a column address CA from the buffer block 560. The data input and output block 550 may output the data read by the page buffer block 530 to the buffer block 560 depending on the column address CA. The data input and output block 550 may provide the data received from the buffer block 560 to the page buffer block 530, based on the column address CA.

Through first signal lines SIGL1, the buffer block 560 may receive a command CMD and an address ADDR from an external device and may exchange data “DATA” with the external device. The buffer block 560 may operate under control of the control logic block 570. The buffer block 560 may provide the command CMD to the control logic block 570. The buffer block 560 may provide the row address RA of the address ADDR to the row decoder block 520 and may provide the column address CA of the address ADDR to the data input and output block 550. The buffer block 560 may exchange the data “DATA” with the data input and output block 550.

The control logic block 570 may exchange a control signal CTR L with the external device through second signal lines SIGL2. The control logic block 570 may allow the buffer block 560 to route the command CMD, the address ADDR, and the data “DATA”. The control logic block 570 may decode the command CMD received from the buffer block 560 and may control the nonvolatile memory device 500 based on the decoded command.

In an embodiment, the nonvolatile memory device 500 may be manufactured in a bonding method. The memory cell array 510 may be manufactured by using a first wafer, and the row decoder block 520, the page buffer block 530, the data input and output block 550, the buffer block 560, and the control logic block 570 may be manufactured by using a second wafer. The nonvolatile memory device 500 may be implemented by coupling the first wafer and the second wafer such that an upper surface of the first wafer and an upper surface of the second wafer face each other.

As another example, the nonvolatile memory device 500 may be manufactured in a cell over peri (COP) method. A peripheral circuit including the row decoder block 520, the page buffer block 530, the data input and output block 550, the buffer block 560, and the control logic block 570 may be implemented on a substrate. The memory cell array 510 may be implemented over the peripheral circuit. The peripheral circuit and the memory cell array 510 may be connected by using the through vias.

FIG. 15 is a diagram of a system 1000 to which a storage device is applied, according to one or more example embodiments. The system 1000 of FIG. 15 may be, for example but not limited to, a mobile system, such as a portable communication terminal (e.g., a mobile phone), a smartphone, a tablet personal computer (PC), a wearable device, a healthcare device, or an Internet of things (IOT) device. However, the system 1000 of FIG. 15 is not necessarily limited to the mobile system and, for example but not limited to, may be a PC, a laptop computer, a server, a media player, or an automotive device (e.g., a navigation device).

Referring to FIG. 15, the system 1000 may include a main processor 1100, memories (e.g., 1200a and 1200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some embodiments, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as a static random access memory (SRAM) and/or a dynamic RAM (DRAM), each of the memories 1200a and 1200b may include a non-volatile memory, such as a flash memory, a phase-change RAM (PRAM) and/or a resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVMs (Non-Volatile Memories) 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as a PRAM and/or an RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 100 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as an advanced technology attachment (ATA), a serial ATA (SATA), an external SATA (e-SATA), a small computer small interface (SCSI), a serial attached SCSI (SAS), a peripheral component interconnection (PCI), a PCI express (PCIe), an NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In an embodiment, the electronic device 200 or 300 described with reference to FIGS. 1 to 13 may be implemented with the storage devices 1300a and 1300b. The storage device 1300a or 1300b may internally measure and record the jitter-tolerance JTOL of the receiver 220 or 320 of the host interface 422 by performing the test operation. In an embodiment, the storage device 1300a or 1300b may measure and record the jitter-tolerance JTOL overtime. The storage device 1300a or 1300b may provide test results of the jitter-tolerance JTOL to an external host device depending on a request of the external host device.

The storage device 1300a or 1300b may perform the optimization operation based on the test result. The storage device 1300a or 1300b may adjust an offset of the receiver 220 or 320 of the host interface 422 by performing the optimization operation, and thus, the jitter-tolerance JTOL may be improved.

The storage device 1300a or 1300b may store default offset information of the receiver 220 or 320 of the host interface 422 according to environment information. When the environment information changes, the storage device 1300a or 1300b may change the default offset of the receiver 220 or 320 of the host interface 422. Accordingly, the jitter-tolerance JTOL of the storage device 1300a or 1300b may be improved.

In the above embodiments, components according to the disclosure are described by using the terms “first”, “second”, “third”, etc. However, the terms “first”, “second”, “third”, etc. may be used to distinguish components from each other and do not limit the disclosure. For example, the terms “first”, “second”, “third”, etc. do not involve an order or a numerical meaning of any form.

In the above embodiments, components according to one or more example embodiments of the disclosure may be referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP).

According to one or more example embodiments of the disclosure, a storage device may collect and store a jitter-tolerance JTOL of a receiver communicating with an external host device. Accordingly, even if an environment changes in the process of manufacturing the storage device, the storage device may collect and provide information of the jitter-tolerance JTOL. This may mean that the yield of the storage device may be improved. Also, according to embodiments of the disclosure, the storage device may perform optimization of the receiver based on the collected jitter-tolerance JTOL, and the reliability of the storage device may be improved.

At least one of the components, elements, modules or units (collectively “components” in this paragraph) represented by a block in the drawings, may be embodied as various numbers of hardware, software and/or firmware structures that execute respective functions described above, according to an example embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above example embodiments may be implemented in algorithms that execute on one or more processors. Furthermore, the components represented by a block or processing steps may employ any number of related art techniques for electronics configuration, signal processing and/or control, data processing and the like.

While the disclosure has been described with reference to one or more example embodiments thereof, it will be apparent to those of ordinary skill in the art that various changes and modifications may be made thereto without departing from the spirit and scope of the disclosure as set forth in the following claims and their equivalents.

What is claimed is:

1. A storage device comprising:
a receiver configured to receive a reception signal, filter the reception signal to generate an internal signal, and extract data from the internal signal;
a tester circuit configured to, in a test operation, generate a pattern signal and a jitter signal, combine the pattern signal and the jitter signal to output the reception signal to the receiver, receive the internal signal from the receiver, compare the pattern signal and the internal signal, and output a comparison result of the pattern signal and the internal signal as a test result; and
a controller configured to receive the reception signal and the comparison result.

2. The storage device of claim 1, wherein the tester circuit is configured to, based on the pattern signal and the internal signal coinciding with each other, output pass information as the comparison result, and
wherein the tester circuit is configured to, based on the pattern signal and the internal signal not coinciding with each other, output fail information as the comparison result.

3. The storage device of claim 1, wherein the tester circuit is configured to, based on a test condition being satisfied, perform the test operation by generating the pattern signal and the jitter signal, outputting the reception signal, receiving the internal signal, comparing the pattern signal and the internal signal, and outputting the comparison result.

4. The storage device of claim 3, wherein the test condition is satisfied based on an occurrence of at least one of an event that a power starts to be supplied to the storage device, an event that a temperature range of the storage device changes, an event that a voltage range of the storage device changes, and an event that a command for the test operation is received from an external device.

5. The storage device of claim 3, wherein the controller is configured to store test information and a test result of each of a plurality of test operations, and output the test information and the test result of each of the plurality of test operations to an external device in response to a command received from the external device.

6. The storage device of claim 5, wherein the test condition comprises an occurrence of one of a plurality of different events, and the plurality of test operations respectively correspond to the plurality of different events.

7. The storage device of claim 5, wherein the tester circuit is configured to perform the plurality of test operations independently of each other while sequentially selecting one of a plurality of pattern signals as the pattern signal, and/or
wherein the tester circuit is configured to perform the plurality of test operations independently of each other while sequentially selecting one of a plurality of frequencies of the jitter signal, as a frequency associated with the pattern signal, and/or
wherein the tester circuit is configured to perform the plurality of test operations independently of each other while sequentially selecting one of a plurality of amplitudes of the jitter signal, as an amplitude associated with the pattern signal.

8. The storage device of claim 7, wherein the test information of each of the plurality of test operations includes at least one of information of the selected pattern signal, information of the selected frequency, information of the selected amplitude, information of temperature information of the storage device, information of voltage information of the storage device, and information of a time stamp based on each of the plurality of test operations being performed.

9. The storage device of claim 1, further comprising:
a nonvolatile memory device configured to perform a write operation, a read operation, and an erase operation under control of the controller.

10. The storage device of claim 1, wherein the controller is configured to, based on an optimization condition being satisfied, perform an optimization operation of the receiver by adjusting at least one offset of the receiver based on the comparison result.

11. A storage device comprising:
a receiver configured to receive a reception signal, filter the reception signal to generate an internal signal, and extract data from the internal signal;
a tester circuit configured to, in a test operation, generate a pattern signal and a jitter signal, combine the pattern signal and the jitter signal to output the reception signal to the receiver, receive the internal signal from the receiver, compare the pattern signal and the internal signal, and output a comparison result of the pattern signal and the internal signal as a test result; and
a controller configured to receive the reception signal and the comparison result,
wherein the controller is further configured to, in response to the comparison result indicating a fail that the pattern signal and the internal signal do not coincide with each other, perform an optimization operation of adjusting at least one offset of the receiver, and
wherein the controller is further configured to, in response to the comparison result indicating a pass that the pattern signal and the internal signal coincide with each other, skip the optimization operation.

12. The storage device of claim 11, wherein the controller is further configured to perform the optimization operation in response to an optimization condition being satisfied, and
wherein the optimization condition includes at least one of a condition where a command for the optimization operation is received from an external device, a condition where a power supply to the storage device is initiated, a condition where a temperature range of the storage device changes, and a condition where a voltage range of the storage device changes.

13. The storage device of claim 11, wherein the optimization operation includes:
a first operation in which the controller adjusts the at least one offset of the receiver;
a second operation in which the controller performs the test operation to receive the comparison result based on the adjusted at least one offset; and
a third operation in which the first operation and the second operation are repeated until the comparison result indicates the pass.

14. The storage device of claim 13 wherein the controller is configured to, in the test operation, perform at least one of selecting the pattern signal among a plurality of pattern signals, one frequency among a plurality of frequencies of the jitter signal, and one amplitude among a plurality of amplitudes of the jitter signal and perform one test loop based on the at least one of the selected pattern signal, the selected frequency, and the selected amplitude, and
wherein the controller is configured to, in the test operation, repeat a test loop until the pass or the fail is determined for respective pattern signals of the plurality of pattern signals, and/or for respective frequencies of the plurality of frequencies, and/or for respective amplitudes of the plurality of amplitudes.

15. The storage device of claim 14, wherein the controller is configured to, based on the fail being determined at least once in the test operation, determine that the comparison result does not indicate the pass.

16. The storage device of claim 14, wherein the controller is configured to, based on a number of times of iteration of the test loop of the test operation being greater than a threshold value, decrease a number of a target to be selected in the test operation from among the plurality of pattern signals, the plurality of frequencies, and the plurality of amplitudes.

17. The storage device of claim 16, wherein the controller is configured to, in decreasing the number of the target, exclude at least a portion of the plurality of pattern signals, the plurality of frequencies, and the plurality of amplitudes, of which a probability of an occurrence is lowest from a selection target.

18. The storage device of claim 11, wherein the controller is configured to, based on the optimization operation being activated, perform the optimization operation in response to the comparison result indicating the fail.

19. The storage device of claim 11, wherein the at least one offset of the receiver includes a coefficient of at least one filter of the receiver.

20. An operating method of a storage device which includes a receiver and a tester circuit, the method comprising:
performing, at the tester circuit, a test operation on the receiver by using a pattern signal and a jitter signal; and
setting, at the tester circuit, offsets of the receiver depending on a result of the test operation,
wherein the offsets include default offsets of filters of the receiver according to at least one of a temperature range of the storage device and a voltage range of the storage device, and
wherein the performing of the test operation includes:
(i) combining the pattern signal and the jitter signal to be input to the receiver;
(ii) comparing a signal filtered by the receiver with the pattern signal; (iii) repeating operations (i) and (ii) while adjusting the jitter signal, and
(iv) iterating a test loop including operations (i)-(iii) while adjusting at least one offset of the receiver, until the pattern signal and the filtered signal coincide with each other.
